(19) United States
(12) Patent Application Publication
(10) Pub. No.: US 2003/0054637 A1
(43) Pub. Date: Mar. 20, 2003

(54) Method for forming silicide

(75) Inventor: Tien-Chu Yang, Hsinchu (TW)

Correspondence Address: LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/956,117

(22) Filed: Sep. 20, 2001

(51) Int. Cl. H01L 21/44

(52) U.S. Cl. 438/682; 438/655; 438/657

(57) ABSTRACT

A method for forming silicide, at least includes following essential steps: provide substrate which is covered with semiconductor structure which has rugged surface; form silicon layer on semiconductor structure; form a metal layer on silicon layer; form capping layer on metal layer; and perform thermal process to form silicide layer by reacting of metal layer and silicon layer, where the thermal stability of capping layer is superior to the thermal stability of silicide layer. The method further perform a pattern process to form numerous conductive lines at least are made of silicide layer. One main characteristic of this invention is to limit agglomeration of silicide by high thermal stable capping layer, such that occurrence of electrical open induced by open of silicide is reduced.

### BACKGROUND OF THE INVENTION

1. Field of the Invention

This invention relates generally to a method for forming silicide, and particularly relates to a method for forming silicide lines with low sheet resistance and high thermal stability.

2. Description of the Prior Art

Because silicide has many advantages such as low sheet resistance, low contact resistance to silicon, good adhesion to silicon, and low interfacial stress, silicide has been widespreadly used to metal contact, gate conductor, and local interconnect.

Fabrication of silicide could be briefly divided into two categories: one is that directly deposits silicide on substrate and then forms required silicide structures by performing a pattern process; another is that forms metal layer on silicon substrate, next, performs thermal process to form silicide. Moreover, because not each kind of silicide can be formed by deposition, the latter category is more popular than the former category. Especially, distribution of silicide layer can be controlled by predetermining distribution of silicon layer and save pattern process, this is so-called self-aligned silicide process.

Silicide is generally thermally formed by reaction of metal and silicon, agglomeration phenomenon is inevitable while temperature of sequent process(es) is higher or thermal period of sequent process(es) is longer. Moreover, agglomeration usually induces some problems, such as decreased junction leakage, necking of silicide line, open of silicide line, and increase of silicide resistance. Refers to two indication figures: FIG. 1A which shows agglomeration is not occurred and FIG. 1B which shows agglomeration is occurred, where semiconductor structure 11 locates on substrate 10 and silicide 12 locates on semiconductor structure 11. Researches discover that agglomeration phenomenon is related to structure recombination, and then sheet resistance of thicker and wider silicide structure is hardly degraded by agglomeration phenomenon than that of thinner and narrower silicide structure. In other words, thermal stability of silicide structure is proportional to thickness and width of silicide structure.

Therefore, because scale of silicide structure must be continually shrunk whenever critical scale of semiconductor structure is continually shrunk, it is indisputable that silicide agglomeration is an inevitable problem, especially for narrower silicide line and thinner silicide film.

Besides, owing to structure of semiconductor device is getting complex, silicide lines usually are not formed on a smooth topography but on a rugged semiconductor structure with steps and corners. Under the present circumstances, stress of silicide at corners of semiconductor structure is larger than stress of silicide at flat part of semiconductor structure, and then silicide film do not tend to be located on corners during period of thermal process for forming silicide layer, such that necking of silicide line and open of silicide line are unavoidable. Besides, the physical vapor deposited metal film is hard to conformally form on the sidewalls of silicon steps, which makes the metal layer thinner on sidewalls. Consequently, the formed silicide is thinner at structure's sidewall. Thus, during the subsequent thermal cycles, silicide agglomeration is easy to occur in the above mentioned sidewall areas, especially, in some high-aspect-ratio trenches. Refers to FIG. 1C and FIG. 1D, where silicon layer 13 is essentially conformal but metal layer 14 is not conformal on sidewall of hole 15, and hence formed thickness of silicide 12 on sidewall is less than that of silicide 12 on flat part of structure.

Accordingly, thermal stability of silicide line tend to be degraded by decreasing the line width, the aggressive topography underneath the silicide line and the thickness uniformity of silicide lines. It is desired to develop a method for improve above disadvantages, such that silicide structure, especially silicide line, could be further properly used by very large scale integration (VLSI) and ultra large scale integration (ULSI).

### SUMMARY OF THE INVENTION

One main object of the invention is to reduce or even eliminate the effect of silicide agglomeration.

Another object of the invention is to present a method for forming silicide lines, where silicide lines are formed on a rugged topography.

Still an essential object of the invention is to present a method for enhancing thermal stability of silicide without obviously modifying well-known fabrication of silicide.

One preferred embodiment of this invention is a method for forming silicide, at least includes following essential steps: first, provide a semiconductor structure which has rugged topography, then form silicon layer on semiconductor structure. Then, form a metal layer on silicon layer and form capping layer on metal layer. Next, perform thermal process to form silicide layer by reacting of metal layer and silicon layer, where thermal stability of silicide layer is less than thermal stability of capping layer. Further, perform a pattern process to from conductive lines from the silicide layer.

One main characteristic of this invention is to limit the grain reconstruction of silicide by capping layer with high thermal stability, such that occurrence of agglomeration of silicide is suppnessed. Moreover, whenever material(s) of capping layer is conductive material, because capping layer is not as susceptible as silicide layer to be agglomerative, the conductive capping layer could conduct electric current even silicide line is open, and then open of conductive lines could be properly reduced.

### BRIEF DESCRIPTION OF THE DRAWINGS

A more complete appreciation and many of the attendant advantages will be readily obtained as the same becomes better understood by reference to the following detailed description when considered in connection with the accompanying drawings.

FIG. 1A through FIG. 1D are cross-sectional illustrations for showing effect of agglomeration phenomenon and non-uniform formation of silicide films;

FIG. 2A through FIG. 2E are cross-sectional illustrations about some essential steps of one preferred embodiment of this present invention; and

FIG. 3 is an essential flow-chart of another preferred embodiment of this present invention

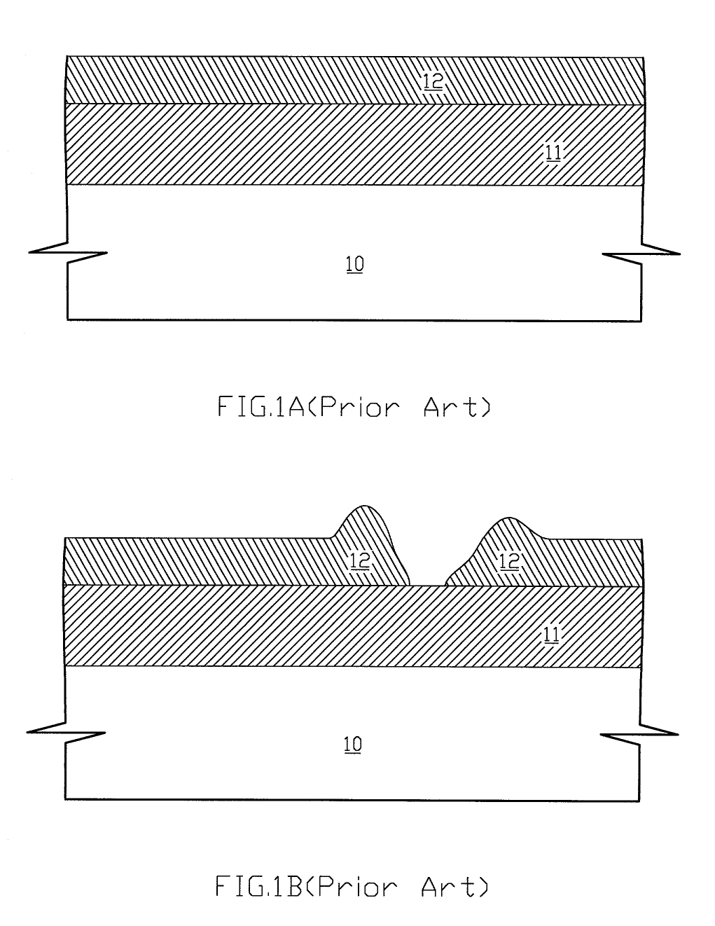

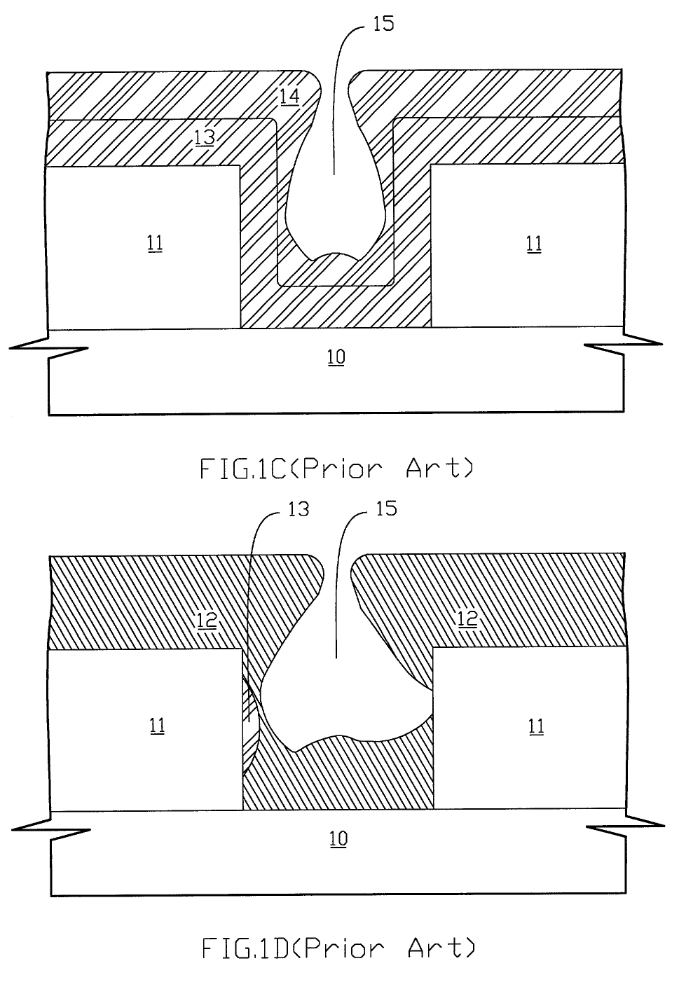

### DESCRIPTION OF THE PREFERRED EMBODIMENT

Some preferred embodiments are discussed in detail below, and are used to clearly explain this invention. However, it should be emphasized that this claimed invention could be applied to other applications and is not limited by these embodiments. Therefore, available scope of this invention is not limited by present embodiments but the claims.

Focus on unavoidable defects of silicide line on a rugged topography: stress on corners is larger than stress on flats which induces silicide grains tending to agglomerat on corners, and thickness of metal and silicon on sidewalls is larger than thickness of metal and silicon on flats which induces silicide grains are tending to be agglomerated on sidewalls. The applicant of this invention presents an idea: although both non-uniform stress and non-uniform thickness almost are inevitable, growth and re-construction of silicide grains could be limited by covering a capping layer on metal layer, especially by conformally covering a capping layer.

In short, the essential of this invention is to reduce the agglomeration phenomenon, to limit reconstruction of silicide grains by covering metal layer with a capping layer which has a larger thermal stability than silicide, such that thermal stability of silicide films is improved especially on places with high stress or low thickness. In contrast, most of well-known prior arts reduce the agglomeration of silicide induced by non-uniform stress and/or non-uniform thickness by complex and expensive methods such as reducing temperature of silicide fabrication, changing material of silicide and modifying silicide fabrication. Therefore, the invention obviously is a simple and cheap method, also is a easy method to be incorporate with available semiconductor fabrication.

Significantly, because this invention could effectively prevent the silicide layer from agglomeration in case of non-uniform stress and/or non-uniform thickness, the invention therefore could effectively enhance thermal stability. Moreover, whatever material of capping layer is conductive, current still could be conducted in continuous capping layer on silicide layer accordingly, a conductive line consisting of capping layer and silicide layer can increase the thermal stability.

One preferred embodiment of this invention is a method for forming silicide, at least includes following essential steps:

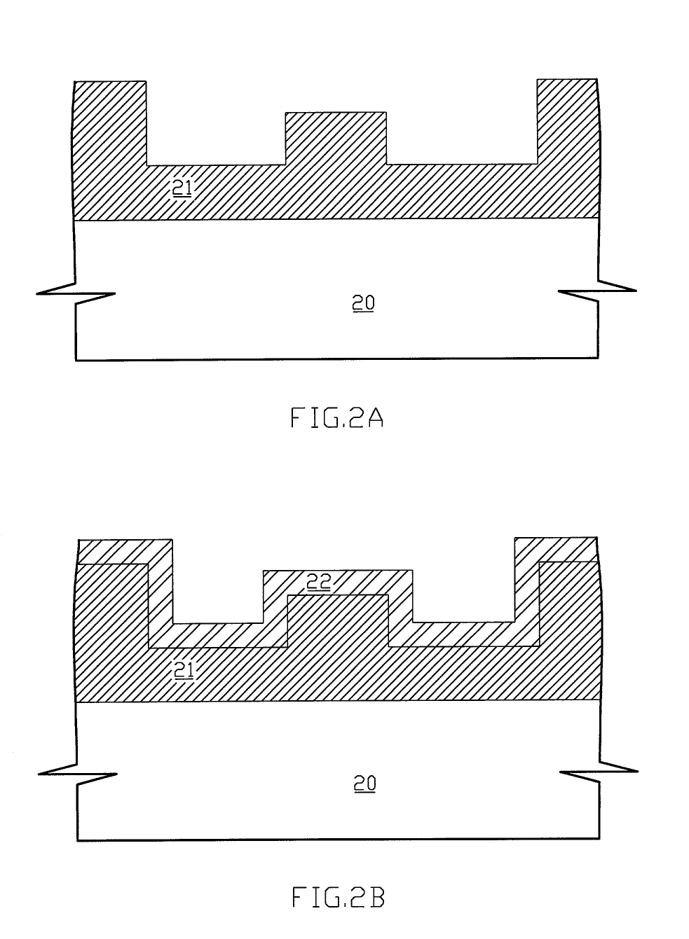

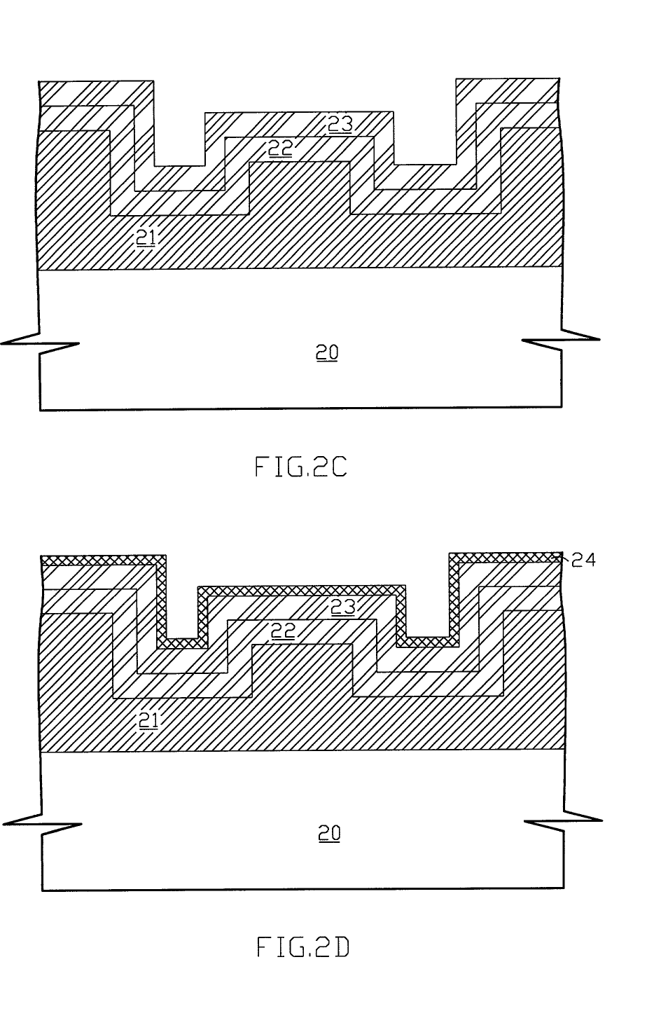

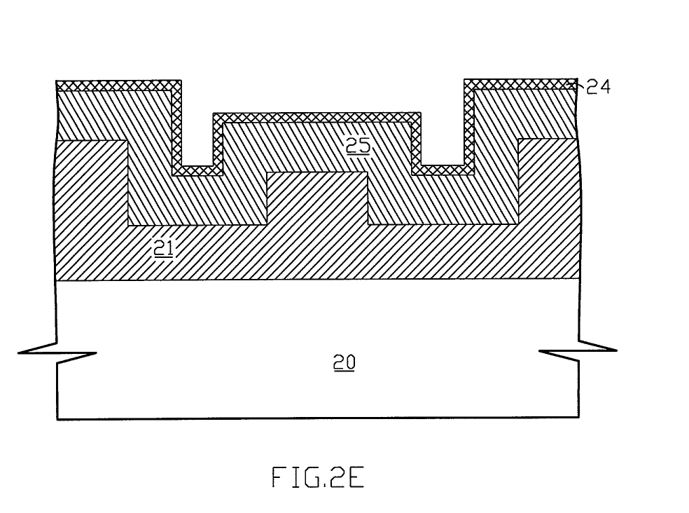

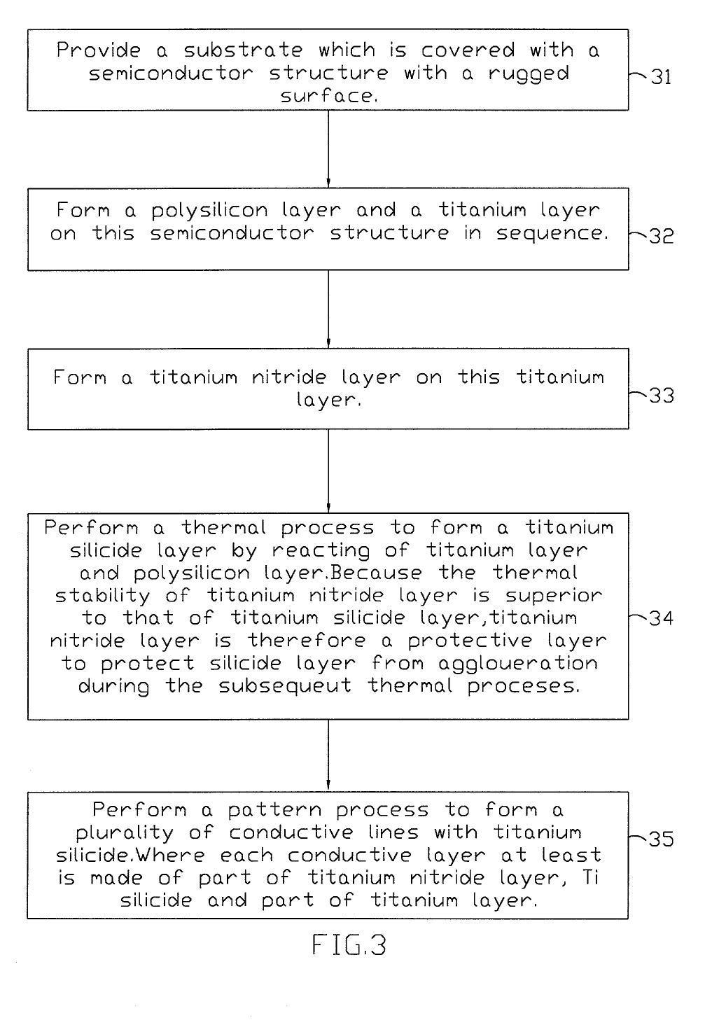

As FIG. 2A shows, providing substrate 20, where topography of substrate 20 is covered with semiconductor structure 21 which has a rugged topography. Semiconductor structure 21 could be numerous gates and numerous dielectric layers where gates and dielectric layers are alternate to each other, semiconductor structure 21 also could be numerous bit line dielectric layers. Moreover, in order to simplify figures and emphasize effect of this invention, shown topography of semiconductor structure 21 are combination of a series of steps, but this invention is not limited details of rugged topography.

As FIG. 2B shows, form silicon layer 22 on semiconductor structure 21. Material of silicon layer 22 usually is chosen from the group consisting of polysilicon layer, amorphous silicon layer, and expitaxy silicon layer.

As FIG. 2C shows, form metal 23 layer on silicon layer 22. Material of metal layer 22 usually is chosen from the group of titanium, cobalt, tungsten, nickel, manganese, platinum, tantalum, and palladium.

As FIG. 2D shows, form capping layer 24 on metal layer 23. Capping layer 24 uniformly covers metal layer 23, and thermal stability of capping layer 24 must be larger than the thermal stability of silicide which is compound of metal layer 23 and silicon layer 22. Herein, capping layer 24 usually conformally covers metal layer 23. Thus, surface diffusion degree of silicide grain is limited during thermal treatment in sequent process(es), and then re-construction velocity of silicide grains induced by thermal treatment is decreased. Herein, material of capping layer 24 could be the nitride compound of material of metal layer 23, nitrided metal, or conductive material. Besides, capping layer 24 usually is thinner than metal layer 23.

As FIG. 2E shows, perform a thermal process to from silicide layer 25 by reacting of metal layer 23 and silicon layer 22. Because the thermal stability of capping layer 24 is superior to that of silicide layer 25, capping layer 24 is stable during the subsequently thermal process. Significantly, because capping layer 24 is directly capped on silicide layer 25, potential electrical open induced by rifts in silicide layer 25 are further reduced while capping layer 24 is a conductive material. In other words, this invention provide a method to form good conductive lines with highly thermal stable silicide on a topography. Further, to simply all related figures, FIG. 2E only illustrates the case that all silicon layer and all metal 23 are consumed to form silicide layer 25.

Silicide lines or conductive lines with silicide are formed by patterning the composite film of silicide and metal. The pattern process could be the following optional steps: perform a pattern process such that numerous silicide lines are made of silicide layer 25; perform a pattern process such that numerous lines are made of both silicide layer and part of unreacted silicon layer 22; perform a pattern process such that numerous lines are made of both silicide layer 25 and part of unreacted metal layer 23, and both silicon and capping layer 24; perform a pattern process such that numerous lines are made of both silicide layer 25 and capping layer 24 whatever capping layer 24 is made of conductive material. Of course, in order to simply so-called pattern process, material of capping layer 24 usually is chosen to be compatible with silicide layer 25 in etching process.

Another preferred embodiment is a practical application of this invention: a method for forming conductive lines with titanium silicide. This embodiment at least includes following essential steps:

As block 31 shows, provide a substrate which is covered with a semiconductor structure with a rugged surface.

As block 32 shows, form a polysilicon layer and a titanium layer on this semiconductor structure in sequence.

As block 33 shows, form a titanium nitride layer on this titanium layer.

As block 34 shows, perform a thermal process to form a titanium silicide layer by the reaction of both titanium layer and polysilicon layer. Because thermal stability of titanium nitride layer is superior to that of silicide layer, titanium nitride layer hence is stable during the subsequent thermal process to constrain silicide layer from agglomeration.

As block 35 shows, perform a pattern process to form a plurality of conductive lines with titanium silicide. Where each conductive layer at least is made of both titanium nitride layer and titanium silicide layer. Moreover, whenever polysilicon layer is not totally consumed during the silicide formation, each conductive line at least is made of titanium silicide layer, titanium nitride layer, and unreacted polysilicon layer. Similarly, whenever titanium layer is not totally consumed after silicide layer is formed, each conductive line at least is made of titanium silicide layer, titanium nitride layer, and unreacted titanium layer.

In addition, even titanium silicide layer is open or necking during the subsequent thermal processes, because titanium nitride is conductive material, the existence of titanium nitride layer could ensure the function of conductive lines.

Furthermore, titanium nitride layer and nitride silicide layer could be etched by same etching process, and then pattern process is simplified.

From the foregoing it will be appreciated that, although specific embodiments of the invention have been described herein for the purpose of illustration, various modifications may be made without deviating from the spirit and scope of the invention. Accordingly, the invention is not limited except as by the appended claims.

What is claimed is

1. A method for forming silicide, comprising:
providing a semiconductor structure which has a rugged topography;
forming a silicon layer on said semiconductor structure;
forming a metal layer on said silicon layer;
forming a capping layer on said metal layer; and
performing a thermal process, so let a silicide layer is formed by the reaction of said metal layer and said silicon layer, wherein the thermal stability of said capping layer is superior to the thermal stability of said silicide layer.

2. The method of claim 1, further comprises a step of performing a pattern process such that a plurality of silicide lines are made from said silicide layer.

3. The method of claim 1, further comprises a step of performing a pattern process such that a plurality of lines are formed by reacting of said silicide layer and part of unreacted said silicon layer.

4. The method of claim 1, further comprises a step of performing a pattern process such that a plurality of lines by reacting of said silicide layer and said capping layer whatever said capping layer is made of conductive material.

5. The method of claim 1, said semiconductor structure comprising a plurality of gates and a plurality of dielectric layers, said gates and said dielectric layer being alternate to each other.

6. The method of claim 1, said semiconductor structure comprising a plurality of bit line dielectric layers.

7. The method of claim 1, said silicon layer is chosen from the group consisting of polysilicon layer, amorphous silicon layer, and expitaxy silicon layer.

8. The method of claim 1, wherein material of said metal layer is chosen from the group of titanium, cobalt, tungsten, nickel, manganese, platinum, tantalum, and palladium.

9. The method of claim 1, wherein said capping layer is conformally deposited on said metal layer.

10. The method of claim 1, wherein said capping layer is not open during subsequent said thermal process.

11. The method of claim 1, wherein said capping layer and said silicide layer could be etched by same etching process.

12. The method of claim 1, wherein material of said capping layer is the nitride compound of said metal layer.

13. The method of claim 1, wherein material of said capping layer is the nitriding metal.

14. The method of claim 1, wherein material of said capping layer is the conductive material.

15. The method of claim 1, wherein said capping layer is thinner than said metal layer.

16. A method for forming conductive lines with titanium silicide, comprising:
providing a substrate, said substrate being covered with a semiconductor structure which has a rugged topography;
forming a polysilicon layer on said semiconductor structure;
forming a titanium layer on said polysilicon layer;
forming a titanium nitride layer on said titanium layer;
performing a thermal process, such that a titanium silicide layer is formed by reacting of said titanium layer and said polysilicon layer; and
performing a pattern process to form a plurality of conductive lines, each said conductive layer at least being made of said titanium silicide layer and said titanium nitride layer.

17. The method of claim 16, wherein said titanium nitride layer is not open during the subsequent thermal process.

18. The method of claim 16, wherein each open of said titanium nitride layer is not overlapped by any open of said titanium silicide layer.
